(19) United States
(12) Patent Application Publication
(10) Pub. No.: US 2019/0387648 A1
(43) Pub. Date: Dec. 19, 2019

(54) ELECTROMAGNETIC WAVE SHIELD STRUCTURE AND PRODUCTION METHOD THEREFOR

(71) Applicant: ZEON CORPORATION, Chiyoda-ku Tokyo (JP)

(72) Inventor: Tsutomu NAGAMUNE, Chiyoda-ku, Tokyo (JP)

(73) Assignee: ZEON CORPORATION, Chiyoda-ku Tokyo (JP)

(21) Appl. No.: 16/337,055

(22) PCT Filed: Oct. 3, 2017
(86) PCT No.: PCT/JP2017/036024

§ 371 Date: Jul. 17, 2019

(30) Foreign Application Priority Data
Oct. 4, 2016 (JP) 2016-196725

(51) Int. Cl. H05K 9/00; B32B 27/28; B32B 5/02; B32B 27/12; C01B 32/168

(52) U.S. Cl. CPC H05K 9/009; B32B 27/281; B32B 5/02; B32B 2307/212; C01B 32/168; B32B 2262/106; B32B 2307/206; B32B 27/12

(57) ABSTRACT

An electromagnetic wave shield structure comprises an electromagnetic wave shield layer that contains surface-treated fibrous carbon nanostructures obtained by treating surfaces of fibrous carbon nanostructures and has a weight per unit area of 0.5 g/m² or more and 30 g/m² or less.

### TECHNICAL FIELD

The present disclosure relates to an electromagnetic wave shield structure and a production method for an electromagnetic wave shield structure.

### BACKGROUND

Electromagnetic interference countermeasures have been conventionally taken to prevent functional failures and the like caused by electromagnetic wave noise from electronics. Electromagnetic interference countermeasures are typically required to restrict the flow of electromagnetic waves of unnecessary frequencies while allowing electromagnetic waves of necessary frequencies to flow. To restrict the flow of electromagnetic waves of unnecessary frequencies, the development of materials having performance (electromagnetic wave shield performance) of shielding electromagnetic waves of unnecessary frequencies (by reflection and/or absorption) without transmitting them is needed. Moreover, to prevent other electromagnetic interference caused by electromagnetic waves reflected during electromagnetic wave shielding, the development of materials excellent in performance (electromagnetic wave absorption performance) of absorbing and removing electromagnetic waves of unnecessary frequencies among materials excellent in electromagnetic wave shield performance is particularly needed.

As conventional materials for electromagnetic interference countermeasures, for example, materials containing conductive materials are known.

For example, PTL 1 discloses a molded product obtained by vacuum pressing a resin composition yielded by kneading, in polypropylene and polycarbonate, carbon black which is a conductive material in a predetermined dispersed state as electromagnetic wave absorbent particles. The molded product in PTL 1 has enhanced electromagnetic wave absorptance in a frequency band of 1 GHz to 10 GHz.

PTL 2 discloses an electromagnetic wave absorber obtained by pressing a material yielded by kneading an ethylene-based resin and, as a nanosized carbon material, carbon nanotubes and/or fullerenes which are conductive materials. The electromagnetic wave absorber in PTL 2 delivers electromagnetic wave absorption performance when electric waves in a relatively high frequency band of 1 GHz to 20 GHz are incident.

### CITATION LIST

### Patent Literatures

PTL 1: JP 2015-15373 A
PTL 2: JP 2003-158395 A

### SUMMARY

### Technical Problem

In recent years, millimeter waves, i.e. electromagnetic waves having a short wavelength of about 10 mm to 1 mm (extremely high frequency of about 30 GHz to 300 GHz), are used in various technologies such as satellite communication, radars installed in automobile collision prevention mechanisms and the like, and wireless access. Countermeasures against electromagnetic interference caused by electromagnetic waves are also needed in such an extremely high frequency band, in order to transmit a larger amount of information with reduced noise.

However, according to research by the inventor, the molded product described in PTL 1 and the electromagnetic wave absorber described in PTL 2 failed to exhibit excellent electromagnetic wave shield performance and electromagnetic wave absorption performance for electromagnetic waves in an extremely high frequency band of millimeter wave level with frequencies of 30 GHz or more.

It could therefore be helpful to provide an electromagnetic wave shield structure excellent in electromagnetic wave shield performance and electromagnetic wave absorption performance in an extremely high frequency band, and a production method therefor.

### Solution to Problem

The inventor made extensive studies to achieve the object stated above. The inventor consequently discovered that, for example, an electromagnetic wave shield structure including an electromagnetic wave shield layer that contains fibrous carbon nanostructures such as carbon nanotubes and has a surface density in a predetermined range delivers excellent electromagnetic wave shield performance in a high frequency band. However, the electromagnetic wave shield structure including such an electromagnetic wave shield layer does not have sufficient electromagnetic wave absorption performance, although it delivers high electromagnetic wave shield performance.

The inventor made further studies, and discovered that, by using an electromagnetic wave shield layer that contains surface-treated fibrous carbon nanostructures and has a surface density in a predetermined range, an electromagnetic wave shield structure excellent in electromagnetic wave shield performance and electromagnetic wave absorption performance can be obtained.

To advantageously solve the problem stated above, an electromagnetic wave shield structure according to the present disclosure comprises an electromagnetic wave shield layer that contains surface-treated fibrous carbon nanostructures obtained by treating surfaces of fibrous carbon nanostructures and has a weight per unit area of 0.5 g/m² or more and 30 g/m² or less. As a result of using an electromagnetic wave shield layer containing surface-treated fibrous carbon nanostructures and having a surface density in the foregoing predetermined range, an electromagnetic wave shield structure excellent in electromagnetic wave shield performance and electromagnetic wave absorption performance in, for example, an extremely high frequency band of 30 GHz or more can be obtained.

In the present disclosure, “fibrous carbon nanostructures” refer to a fibrous carbon material with a fiber diameter of less than 1 μm and an aspect ratio (major axis/minor axis) of 5 or more. “Surface-treated fibrous carbon nanostructures” obtained by surface-treating the fibrous carbon nanostructures typically have the same fiber diameter and aspect ratio as the fibrous carbon nanostructures.

In the present disclosure, “fiber diameter” can be measured by observing a section of the electromagnetic wave shield layer in the thickness direction by a scanning electron micrograph (SEM) or a transmission electron microscope (TEM). Particularly in the case where the fiber diameter is small, the section is preferably observed by a transmission electron microscope (TEM). In the present disclosure, “aspect ratio” can be found by measuring maximum diameters (major axes) and particle diameters (minor axes) in a direction orthogonal to the maximum diameter for a section of the electromagnetic wave shield layer in the thickness direction by a scanning electron micrograph (SEM) and calculating the ratio of the major axis and the minor axis (major axis/minor axis).

Preferably, in the electromagnetic wave shield structure according to the present disclosure, at surfaces of the surface-treated fibrous carbon nanostructures, an amount of an oxygen element is 0.03 times or more and 0.3 times or less an amount of a carbon element and/or an amount of a nitrogen element is 0.005 times or more and 0.2 times or less the amount of the carbon element. As a result of limiting the amount of the oxygen element and/or the amount of the nitrogen element at the surfaces of the surface-treated fibrous carbon nanostructures to the foregoing range, the electromagnetic wave shield structure can more favorably deliver electromagnetic wave shield performance and electromagnetic wave absorption performance in, for example, an extremely high frequency band of 30 GHz or more.

In the present disclosure, the “amount of an oxygen element”, the “amount of a nitrogen element”, and the “amount of a carbon element” can be measured by the method described in the Examples section using an X-ray photoelectron spectrometer.

Preferably, in the electromagnetic wave shield structure according to the present disclosure, at the surfaces of the surface-treated fibrous carbon nanostructures, the amount of the oxygen element is 0.03 times or more and 0.3 times or less the amount of the carbon element and the amount of the nitrogen element is 0.005 times or more and 0.2 times or less the amount of the carbon element. As a result of limiting both the amount of the oxygen element and the amount of the nitrogen element at the surfaces of the surface-treated fibrous carbon nanostructures to the foregoing ranges, the electromagnetic wave shield structure can further favorably achieve electromagnetic wave shield performance and electromagnetic wave absorption performance in, for example, an extremely high frequency band of 30 GHz or more.

Preferably, in the electromagnetic wave shield structure according to the present disclosure, the fibrous carbon nanostructures include carbon nanotubes. As a result of containing surface-treated carbon nanotubes, the electromagnetic wave shield structure can be further improved in electromagnetic wave shield performance and electromagnetic wave absorption performance in, for example, an extremely high frequency band of 30 GHz or more.

Preferably, in the electromagnetic wave shield structure according to the present disclosure, the surface-treated fibrous carbon nanostructures are 75 mass % or more of the electromagnetic wave shield layer. As a result of using the electromagnetic wave shield layer containing surface-treated fibrous carbon nanostructures not less than the foregoing lower limit, the electromagnetic wave shield structure can be further improved in electromagnetic wave shield performance in, for example, an extremely high frequency band of 30 GHz or more, and achieve electromagnetic wave shield performance and electromagnetic wave absorption performance more favorably.

The electromagnetic wave shield structure according to the present disclosure may further comprises an insulating support layer directly or indirectly adhered to the electromagnetic wave shield layer. As a result of the electromagnetic wave shield layer and the insulating support layer being adhered, the durability of the electromagnetic wave shield structure can be enhanced.

To advantageously solve the problem stated above, a production method for an electromagnetic wave shield structure according to the present disclosure is a production method for the electromagnetic wave shield structure described above, and comprises a step (A) of forming an electromagnetic wave shield layer that has a weight per unit area of 0.5 g/m² or more and 30 g/m² or less, using surface-treated fibrous carbon nanostructures obtained by treating surfaces of fibrous carbon nanostructures, wherein the step (A) includes: a step (A-2) of dispersing the surface-treated fibrous carbon nanostructures in a solvent to obtain a dispersion liquid; and a step (A-3) of removing the solvent from the dispersion liquid to form the electromagnetic wave shield layer. As a result of removing the solvent from the dispersion liquid and forming the electromagnetic wave shield layer, the uniformity of the electromagnetic wave shield layer can be enhanced, and the electromagnetic wave shield performance and the electromagnetic wave absorption performance of the electromagnetic wave shield structure can be further improved. The electromagnetic wave shield structure obtained by this production method is excellent in electromagnetic wave shield performance and electromagnetic wave absorption performance in, for example, an extremely high frequency band of 30 GHz or more.

Preferably, in the production method for an electromagnetic wave shield structure according to the present disclosure, in the step (A-3), the dispersion liquid is filtered to remove the solvent. As a result of removing the solvent by filtering the dispersion liquid, for example, the electromagnetic wave shield layer included in the electromagnetic wave shield structure excellent in electromagnetic wave shield performance and electromagnetic wave absorption performance in an extremely high frequency band can be formed easily while also removing impurities.

Preferably, in the production method for an electromagnetic wave shield structure according to the present disclosure, in the step (A-3), the dispersion liquid is dried to remove the solvent. As a result of removing the solvent by drying the dispersion liquid, the electromagnetic wave shield layer included in the electromagnetic wave shield structure excellent in electromagnetic wave shield performance and electromagnetic wave absorption performance in an extremely high frequency band can be formed more easily.

Preferably, in the production method for an electromagnetic wave shield structure according to the present disclosure, the step (A) further includes a step (A-1) of subjecting the surfaces of the fibrous carbon nanostructures to plasma treatment and/or ozone treatment to obtain the surface-treated fibrous carbon nanostructures. As a result of performing at least one of plasma treatment and ozone treatment, surface-treated fibrous carbon nanostructures having a desired surface state can be obtained easily.

### Advantageous Effect

It is thus possible to provide an electromagnetic wave shield structure excellent in electromagnetic wave shield performance and electromagnetic wave absorption performance in an extremely high frequency band, and a production method therefor.

### DETAILED DESCRIPTION

Embodiments of the present disclosure will be described in detail below.

An electromagnetic wave shield structure according to the present disclosure is capable of favorably absorbing and shielding electromagnetic waves in an extremely high frequency band of 30 GHz or more in particular. Such an electromagnetic wave shield structure according to the present disclosure is suitable for use in fields utilizing millimeter waves, e.g. electric wave astronomy, satellite communication, various radars such as automobile radar brakes, and wireless access such as next-generation wireless LAN, without being limited thereto.

The electromagnetic wave shield structure according to the present disclosure can be produced by, for example, a production method for an electromagnetic wave shield structure according to the present disclosure.

(Electromagnetic wave shield structure) The electromagnetic wave shield structure according to the present disclosure may be composed only of one electromagnetic wave shield layer having a predetermined composition, be composed only of two or more such electromagnetic wave shield layers, or be a laminate including one or more such electromagnetic wave shield layers and, for example, an optional other constituent member such as an insulating support layer.

<Electromagnetic Wave Shield Layer>

The electromagnetic wave shield layer needs to contain surface-treated fibrous carbon nanostructures obtained by treating the surfaces of fibrous carbon nanostructures, and be included in the electromagnetic wave shield structure in a predetermined surface density (i.e. weight per unit area (g/m²), hereafter also referred to as “mass per unit area”). The electromagnetic wave shield layer may further contain other components besides the surface-treated fibrous carbon nanostructures. Unless the electromagnetic wave shield layer contains the surface-treated fibrous carbon nanostructures and is included in the electromagnetic wave shield structure in the predetermined mass per unit area, the electromagnetic wave shield structure cannot achieve excellent electromagnetic wave shield performance and electromagnetic wave absorption performance in, for example, an extremely high frequency band of 30 GHz or more.

<<Mass Per Unit Area>>

The weight per unit area (mass per unit area) of the electromagnetic wave shield layer included in the electromagnetic wave shield structure according to the present disclosure needs to be 0.5 g/m² or more and 30 g/m² or less. If the mass per unit area is less than the foregoing lower limit, the electromagnetic wave shield performance and the electromagnetic wave absorption performance of the electromagnetic wave shield structure in, for example, an extremely high frequency band of 30 GHz or more cannot be enhanced sufficiently, and the strength is insufficient. If the mass per unit area is more than the foregoing upper limit, the formation of a uniform electromagnetic wave shield layer is difficult. Consequently, the electromagnetic wave shield performance and the electromagnetic wave absorption performance of the electromagnetic wave shield structure in an extremely high frequency band cannot be achieved favorably.

The mass per unit area of the electromagnetic wave shield layer is preferably 1.5 g/m² or more and more preferably 2.0 g/m² or more, and is preferably 29 g/m² or less. If the mass per unit area is in the foregoing range, the electromagnetic wave shield performance and the electromagnetic wave absorption performance of the electromagnetic wave shield structure in an extremely high frequency band can be achieved favorably.

<<Surface-Treated Fibrous Carbon Nanostructures>>

The surface-treated fibrous carbon nanostructures are obtained by treating the surfaces of fibrous carbon nanostructures by any method. Unless the electromagnetic wave shield layer contains the surface-treated fibrous carbon nanostructures, especially the electromagnetic wave absorption performance in an extremely high frequency band is poor, and the electromagnetic wave shield performance and the electromagnetic wave absorption performance cannot be achieved favorably. In terms of achieving excellent electromagnetic wave shield performance and electromagnetic wave absorption performance of the electromagnetic wave shield structure, it is particularly preferable to satisfy the below-described amounts of elements at the surfaces of the surface-treated fibrous carbon nanostructures.

[Fibrous Carbon Nanostructures]

Examples of the fibrous carbon nanostructures include carbon nanotubes and vapor-grown carbon fibers, without being limited thereto. One of these fibrous carbon nanostructures may be used individually, or two or more of these fibrous carbon nanostructures may be used in combination. Of these, the fibrous carbon nanostructures are preferably fibrous carbon nanostructures including carbon nanotubes. As a result of using fibrous carbon nanostructures including carbon nanotubes, the electromagnetic wave shield layer containing the surface-treated fibrous carbon nanostructures enables the electromagnetic wave shield structure to achieve the electromagnetic wave shield performance and the electromagnetic wave absorption performance in an extremely high frequency band more favorably. Moreover, since carbon nanotubes typically have a large specific surface area, the surfaces of the fibrous carbon nanostructures can be easily treated to a desired state, and favorable durability can be achieved even in the case where the electromagnetic wave shield layer is formed in a thin film.

—Properties of Fibrous Carbon Nanostructures—

The average fiber diameter (average diameter (Av)) of the fibrous carbon nanostructures is preferably 0.5 nm or more and more preferably 1 nm or more, and is typically less than 1 μm, preferably 15 nm or less, and more preferably 10 nm or less. If the average diameter (Av) of the fibrous carbon nanostructures is not less than the foregoing lower limit, the electromagnetic wave shield performance and the electromagnetic wave absorption performance in an extremely high frequency band can be further enhanced. Moreover, the surface-treated fibrous carbon nanostructures obtained using the fibrous carbon nanostructures have excellent dispersibility, so that a uniform electromagnetic wave shield layer can be produced more easily. If the average diameter (Av) of the fibrous carbon nanostructures is not more than the foregoing upper limit, the flexibility of the fibrous carbon nanostructures is improved, with it being possible to form an electromagnetic wave shield layer having excellent toughness.

In the present disclosure, the “average fiber diameter (average diameter (Av)) of the fibrous carbon nanostructures” can be obtained as a number-average diameter calculated by measuring the diameters of 100 randomly selected fibrous carbon nanostructures using a scanning electron micrograph (SEM) or a transmission electron microscope (TEM).

Particularly in the case where the diameters of the fibrous carbon nanostructures are small, observation by a transmission electron microscope (TEM) is preferable. The average fiber diameter (average diameter (Av)) of the fibrous carbon nanostructures may be adjusted by changing the production method and the production conditions of the fibrous carbon nanostructures, or adjusted by combining a plurality of types of fibrous carbon nanostructures obtained by different production methods.

The ratio (3σ/Av) of the diameter standard deviation (σ) multiplied by (3σ) relative to the average diameter (Av) of the fibrous carbon nanostructures is preferably more than 0.20 and less than 0.60, more preferably more than 0.25, and further preferably more than 0.40. The use of fibrous carbon nanostructures with 36/Av in the foregoing range enables the electromagnetic wave shield structure to achieve more favorable electromagnetic wave shield performance and electromagnetic wave absorption performance in an extremely high frequency band.

In the present disclosure, the “diameter standard deviation (σ: sample standard deviation) of the fibrous carbon nanostructures” can be obtained by the same method as the foregoing “average diameter (Av)”, and can be adjusted by the same method as the foregoing “average diameter (Av)”.

The average fiber length of the fibrous carbon nanostructures is preferably 100 μm or more, in terms of favorable absorption of electromagnetic waves by the electromagnetic wave shield structure. Meanwhile, longer fibrous carbon nanostructures tend to be more easily damaged by breaking, severing, or the like during surface treatment and dispersion. Therefore, the average fiber length of the fibrous carbon nanostructures is preferably 5000 μm or less.

In the present disclosure, “average fiber length” can be obtained as a number-average major axis by measuring the maximum diameters (major axes) of randomly selected 100 fibrous carbon nanostructures and calculating the average value of the measured major axes by the same method as the foregoing “average fiber diameter (average diameter (Av))”.

The average aspect ratio (major axis/minor axis) of the fibrous carbon nanostructures is typically 5 or more, and preferably more than 10. In the present disclosure, “average aspect ratio” can be obtained by measuring maximum diameters (major axes) and particle diameters (minor axes) in a direction orthogonal to the maximum diameter for randomly selected 100 fibrous carbon nanostructures observed by a scanning electron micrograph (SEM) and calculating the average value of ratios of the major axis to the minor axis (major axis/minor axis).

The BET specific surface area of the fibrous carbon nanostructures is preferably 200 m²/g or more, more preferably 400 m²/g or more, further preferably 600 m²/g or more, and even more preferably 800 m²/g or more, and is preferably 2500 m²/g or less, and more preferably 1200 m²/g or less. If the BET specific surface area of the fibrous carbon nanostructures is not less than the foregoing lower limit, sufficient electromagnetic wave shield performance and electromagnetic wave absorption performance in an extremely high frequency band can be ensured. If the BET specific surface area of the fibrous carbon nanostructures is not more than the foregoing upper limit, the formability of the electromagnetic wave shield layer containing the surface-treated fibrous carbon nanostructures obtained using the fibrous carbon nanostructures can be improved.

In the present disclosure, “BET specific surface area” refers to a nitrogen adsorption specific surface area measured by the BET method.

For example, the fibrous carbon nanostructures are obtained, on a substrate having thereon a catalyst layer for carbon nanotube growth, in the form of an aggregate wherein fibrous carbon nanostructures are aligned substantially perpendicularly to the substrate (aligned aggregate), in accordance with the super growth method described later. The mass density of the fibrous carbon nanostructures in the form of such an aggregate is preferably 0.002 g/cm³ or more, and is preferably 0.2 g/cm³ or less. If the mass density is not more than the foregoing upper limit, the fibrous carbon nanostructures and the surface-treated fibrous carbon nanostructures are homogeneously dispersed because binding among the fibrous carbon nanostructures is weakened. Thus, an electromagnetic wave shield structure excellent in electromagnetic wave shield performance and electromagnetic wave absorption performance can be produced more favorably. If the mass density is not less than the foregoing lower limit, the unity of the fibrous carbon nanostructures can be improved, thus preventing the fibrous carbon nanostructures from becoming unbound and making the fibrous carbon nanostructures easier to handle.

The fibrous carbon nanostructures that are used typically take a normal distribution when a plot is made of diameter measured as described above on the horizontal axis and the frequency on the vertical axis, and Gaussian approximation is made.

The concentration of metal impurities in the fibrous carbon nanostructures is preferably less than 5000 ppm and more preferably less than 1000 ppm, in terms of improving the life property of the electromagnetic wave shield layer and the electromagnetic wave shield structure. Such metal impurities can be caused, for example, by metal catalysts used in the production of the fibrous carbon nanostructures.

Herein, the “concentration of metal impurities” can be measured, for example, by a transmission electron microscope (TEM), a scanning electron microscope (SEM), energy dispersive X-ray analysis (EDAX), a vapor-phase decomposition device and ICP mass spectrometry (VPD, ICP/MS), etc.

—Properties of Fibrous Carbon Nanostructures Including Carbon Nanotubes—

The fibrous carbon nanostructures including carbon nanotubes are not limited, and may be composed solely of carbon nanotubes (hereinafter also referred to as “CNTs”) or may be a mixture of CNTs and fibrous carbon nanostructures other than CNTs.

In the case of using fibrous carbon nanostructures including CNTs, any type of CNTs may be used in the fibrous carbon nanostructures, such as, for example, single-walled carbon nanotubes and/or multi-walled carbon nanotubes, with single- to up to 5-walled carbon nanotubes being preferred, and single-walled carbon nanotubes being more preferred. The use of single-walled carbon nanotubes allows for further improvement in the electromagnetic wave absorption performance of the electromagnetic wave shield structure because of high electrical and heat conductivity. Moreover, since single-walled carbon nanotubes typically have light weight, high strength, and high flexibility, for example, the electromagnetic wave shield layer included in the electromagnetic wave shield structure can be easily thinned.

In view of the above, the CNTs in the fibrous carbon nanostructures preferably exhibit a radial breathing mode (RBM) peak when evaluated by Raman spectroscopy. Note that no RBM appears in the Raman spectrum of CNTs composed solely of multi-walled carbon nanotubes having three or more walls.

In a Raman spectrum of the CNTs in the fibrous carbon nanostructures, the ratio of G band peak intensity to D band peak intensity (G/D ratio) is preferably 1 or more and 20 or less. A G/D ratio of 1 or more and 20 or less allows for improved dispersibility of the surface-treated fibrous carbon nanostructures obtained using the fibrous carbon nanostructures, as a result of which an electromagnetic wave shield structure excellent in electromagnetic wave shield performance and electromagnetic wave absorption performance in an extremely high frequency band can be produced easily.

The content proportion of the carbon nanotubes in the fibrous carbon nanostructures is preferably 50 mass % or more and more preferably 90 mass % or more, and may be 100 mass %. In the case where the fibrous carbon nanostructures are a mixture of single-walled carbon nanotubes and multi-walled carbon nanotubes, the content proportion of the single-walled carbon nanotubes is preferably 50 mass % or more with respect to 100 mass % of the fibrous carbon nanostructures.

The content proportion of each type of carbon nanotubes can be calculated, for example, from a number ratio obtained through observation under a transmission electron microscope (TEM).

The fibrous carbon nanostructures including carbon nanotubes preferably exhibit a convex upward shape in a t-plot.

Herein, “t-plot” can be obtained from the adsorption isotherm of the fibrous carbon nanostructures measured by the nitrogen gas adsorption method by converting the horizontal axis to the average thickness t (nm) of an adsorbed layer of nitrogen gas corresponding to the relative pressure (t-plot method of de Boer et al.). In the case where the fibrous carbon nanostructures including carbon nanotubes have a convex upward t-plot shape, the fibrous carbon nanostructures have a large internal specific surface area as a proportion of total specific surface area, and there are a large number of openings in the carbon nanotubes or the like constituting the fibrous carbon nanostructures. This enables the electromagnetic wave shield structure including the electromagnetic wave shield layer containing the carbon nanotubes or the like to deliver electromagnetic wave shield performance and electromagnetic wave absorption performance in an extremely high frequency band more favorably.

The total specific surface area S1 of the fibrous carbon nanostructures including carbon nanotubes obtained from a t-plot is preferably 400 m²/g or more and more preferably 800 m²/g or more, and is preferably 2500 m²/g or less and more preferably 1200 m²/g or less. The internal specific surface area S2 of the fibrous carbon nanostructures including carbon nanotubes obtained from a t-plot is preferably 30 m²/g or more, and is preferably 540 m²/g or less. If S1 is not less than the foregoing lower limit, incident electromagnetic waves are reflected more at the surfaces and inside of the fibrous carbon nanostructures including carbon nanotubes, enabling the electromagnetic wave shield structure to deliver more favorable electromagnetic wave shield performance and electromagnetic wave absorption performance in an extremely high frequency band. If S2 is not less than the foregoing lower limit, incident electromagnetic waves are multiple-reflected more at the inside of the fibrous carbon nanostructures including carbon nanotubes, enabling the electromagnetic wave shield structure to particularly deliver more favorable electromagnetic wave absorption performance in an extremely high frequency band.

The ratio (S2/S1) of the internal specific surface area S2 to the total specific surface area S1 of the fibrous carbon nanostructures including carbon nanotubes is preferably 0.05 or more, and is preferably 0.30 or less. If S2/S1 is not less than the foregoing lower limit, incident electromagnetic waves are multiple-reflected more at the inside of the fibrous carbon nanostructures including carbon nanotubes, enabling the electromagnetic wave shield structure to particularly deliver more favorable electromagnetic wave absorption performance at an extremely high frequency band. If S2/S1 is not more than the foregoing upper limit, incident electromagnetic waves are reflected more at the surfaces and inside of the fibrous carbon nanostructures including carbon nanotubes, enabling the electromagnetic wave shield structure to deliver more favorable electromagnetic wave shield performance and electromagnetic wave absorption performance in an extremely high frequency band.

The t-plot analysis and the calculation of the total specific surface area S1 and the internal specific surface area S2 can be performed using, for example, a specific surface area/pore size distribution measuring device manufactured by Bel Japan Inc. (product name “BELSORP®-mini” ((BELSORP is a registered trademark in Japan, other countries, or both)).

—Method of Preparing Fibrous Carbon Nanostructures—

The fibrous carbon nanostructures including CNTs can be efficiently produced, for example, by forming a catalyst layer on a substrate surface by wet process in the super growth method (see WO2006/011655) wherein during synthesis of CNTs through chemical vapor deposition (CVD) by supplying a feedstock compound and a carrier gas onto a substrate having thereon a catalyst layer for carbon nanotube production, the catalytic activity of the catalyst layer is dramatically improved by providing a trace amount of an oxidizing agent (catalyst activating material) in the system. Hereinafter, carbon nanotubes obtained by the super growth method are also referred to as “SGCNTs”.

The fibrous carbon nanostructures produced by the super growth method may be composed solely of SGCNTs, or may be composed of SGCNTs and electrically conductive non-cylindrical carbon nanostructures. Specifically, the fibrous carbon nanostructures may include single- or multi-walled flattened cylindrical carbon nanostructures having over the entire length a tape portion where inner walls are in close proximity to each other or bonded together (hereinafter such carbon nanostructures are also referred to as “graphene nanotapes (GNTs)”).

The phrase “having over the entire length a tape portion” as used herein refers to “having a tape portion over 60% or more, preferably 80% or more, more preferably 100% of the length of the longitudinal direction (entire length), either continuously or intermittently”.

<<Other Components>>

Examples of other components that can be contained in the electromagnetic wave shield layer include known additives depending on the intended use, such as dispersants, antioxidants, thermal stabilizers, light stabilizers, ultraviolet absorbers, coloring agents such as pigments, foaming agents, antistatic agents, flame retardants, lubricants, softeners, tackifiers, mold release agents, deodorizers, and perfume.

The electromagnetic wave shield layer may further contain any resin in a small amount as other components. Examples of resin that can be contained in the electromagnetic wave shield layer include resins listed as examples of resin serving as a base material of an insulating material described later.

In the case where the electromagnetic wave shield layer further contains other components, the content proportion of the other components to the electromagnetic wave shield layer is preferably 25 mass % or less, more preferably 10 mass % or less, and further preferably 1 mass % or less. It is even more preferable that the electromagnetic wave shield layer does not substantially contain other components.

Herein, “substantially not containing” means that the content proportion of the other components in the electromagnetic wave shield layer is less than 1 mass %.

In terms of fully utilizing the surface-treated fibrous carbon nanostructures to easily produce the electromagnetic wave shield structure that is excellent in electromagnetic wave shield performance and electromagnetic wave absorption performance and lightweight, the content proportion of the surface-treated fibrous carbon nanostructures to the electromagnetic wave shield layer in the electromagnetic wave shield structure according to the present disclosure is preferably 75 mass % or more, more preferably 90 mass % or more, and further preferably 99 mass % or more. Particularly in terms of further enhancing the electromagnetic wave shield performance of the electromagnetic wave shield layer, it is even more preferable that the electromagnetic wave shield layer is a carbon film not substantially containing other components (e.g. resin) except impurities inevitably mixed in during production, besides the surface-treated fibrous carbon nanostructures.

[Properties of Surface-Treated Fibrous Carbon Nanostructures]

### —Amounts of Oxygen Element and Nitrogen Element—

The amount of the oxygen element (oxygen element content) at the surfaces of the surface-treated fibrous carbon nanostructures contained in the electromagnetic wave shield layer according to the present disclosure is preferably 0.03 times or more the amount of the carbon element, more preferably 0.1 times or more the amount of the carbon element, further preferably 0.18 times or more the amount of the carbon element, and even more preferably 0.2 times or more the amount of the carbon element, and is preferably 0.4 times or less the amount of the carbon element, more preferably 0.35 times or less the amount of the carbon element, and further preferably 0.3 times or less the amount of the carbon element.

Alternatively, the amount of the nitrogen element (nitrogen element content) at the surfaces of the surface-treated fibrous carbon nanostructures contained in the electromagnetic wave shield layer according to the present disclosure is preferably 0.005 times or more the amount of the carbon element and more preferably 0.015 times or more the amount of the carbon element, and is preferably 0.2 times or less the amount of the carbon element and more preferably 0.15 times or less the amount of the carbon element.

If the oxygen element content and/or the nitrogen element content at the surfaces of the surface-treated fibrous carbon nanostructures is not less than the foregoing lower limit, surprisingly the electromagnetic wave absorption performance of the electromagnetic wave shield structure in an extremely high frequency band can be further improved. If the oxygen element content and/or the nitrogen element content at the surfaces of the surface-treated fibrous carbon nanostructures is not more than the foregoing upper limit, the electromagnetic wave shield performance of the electromagnetic wave shield structure can be maintained favorably.

The surface-treated fibrous carbon nanostructures preferably satisfy at least one of the foregoing oxygen element content and nitrogen element content, more preferably satisfy at least the foregoing oxygen element content, and further preferably satisfy both of the foregoing oxygen element content and nitrogen element content.

That is, it is preferable that the amount of the oxygen element at the surfaces of the surface-treated fibrous carbon nanostructures is 0.03 times or more and 0.3 times or less the amount of the carbon element and/or the amount of the nitrogen element at the surfaces of the surface-treated fibrous carbon nanostructures is 0.005 times or more and 0.2 times or less the amount of the carbon element, more preferable that at least the amount of the oxygen element at the surfaces of the surface-treated fibrous carbon nanostructures is 0.03 times or more and 0.3 times or less the amount of the carbon element, and further preferable that the amount of the oxygen element at the surfaces of the surface-treated fibrous carbon nanostructures is 0.03 times or more and 0.3 times or less the amount of the carbon element and the amount of the nitrogen element at the surfaces of the surface-treated fibrous carbon nanostructures is 0.005 times or more and 0.2 times or less the amount of the carbon element. If the oxygen element content and the nitrogen element content are in the foregoing ranges, the electromagnetic wave shield performance and the electromagnetic wave absorption performance of the electromagnetic wave shield structure in an extremely high frequency band can be achieved more favorably.

Various suitable properties of the surface-treated fibrous carbon nanostructures except the amount of each element at the surfaces can be basically the same as various suitable properties of the fibrous carbon nanostructures described above.

The oxygen element content and/or the nitrogen element content at the surfaces of the surface-treated fibrous carbon nanostructures can be controlled to the desired ranges by, for example, adjusting treatment conditions such as surface treatment time and pressure and voltage applied during treatment in the below-described surface treatment method. Normally, the oxygen element content and the nitrogen element content tend to increase as the surface treatment time, the applied pressure, and/or the supplied power is increased. This, however, tends to cause increases in the time and cost required for the surface treatment.

A method of measuring the amount of each of the carbon element, the oxygen element, and the nitrogen element at the surfaces of the surface-treated fibrous carbon nanostructures will be described in detail later in the Examples section. Simply put, the amount of each of these elements can be obtained based on an X-ray diffraction pattern acquired by carrying out X-ray diffraction using AlKa monochromator X rays as an X-ray source in standard condition in accordance with JIS Z 8073, by an X-ray photoelectron spectrometer.

The Examples section describes the case where the amount of each of these elements is measured for surface-treated fibrous carbon nanostructures as a material used in the formation of an electromagnetic wave shield layer. However, the same results can be achieved even when isolating a surface-treated fibrous carbon nanomaterial contained in an electromagnetic wave shield layer by a known appropriate method and performing measurement for the obtained surface-treated fibrous carbon nanomaterial according to the method described in the Examples section.

As the surface-treated fibrous carbon nanostructures having the foregoing surface state, commercial products may be used. Alternatively, for example, the surface-treated fibrous carbon nanostructures having the foregoing surface state may be prepared by preparing the fibrous carbon nanostructures according to the foregoing method and surface-treating the fibrous carbon nanostructures.

[Surface Treatment Method]

The method of treating the surfaces of the fibrous carbon nanostructures is not limited, but is preferably a method by plasma treatment and/or ozone treatment. These treatments may be performed singly or in combination. By performing plasma treatment in any atmosphere, for example, the amounts of elements such as oxygen and nitrogen at the surfaces of the resultant surface-treated fibrous carbon nanostructures can be increased. By performing ozone treatment, the oxygen element content at the surfaces of the resultant surface-treated fibrous carbon nanostructures can be increased.

—Plasma Treatment—

The plasma treatment of the fibrous carbon nanostructures may be carried out by placing the fibrous carbon nanostructures as a surface treatment target into a container containing argon, neon, helium, nitrogen, nitrogen dioxide, oxygen, air, and the like, and exposing the fibrous carbon nanostructures to plasma generated by glow discharge. Examples of discharge modes for plasma generation include (1) DC discharge and low-frequency discharge, (2) radio wave discharge, and (3) microwave discharge.

The plasma treatment conditions are not limited. As the treatment strength, the energy output per unit area of the plasma irradiation surface is preferably 0.05 W/cm² to 2.0 W/cm², and the gas pressure is preferably 5 Pa to 150 Pa. The treatment time may be selected as appropriate, but is typically 1 min to 300 min, preferably 10 min to 180 min, and more preferably 15 min to 120 min.

—Ozone Treatment—

The ozone treatment of the fibrous carbon nanostructures is carried out by exposing the fibrous carbon nanostructures to ozone. The exposure method may be any appropriate method, such as a method of retaining the fibrous carbon nanostructures in an atmosphere containing ozone for a predetermined time, or a method of bringing ozone gas flow into contact with the fibrous carbon nanostructures for a predetermined time.

Ozone that is brought into contact with the fibrous carbon nanostructures can be generated by supplying oxygen-containing gas, such as air, gaseous oxygen, or oxygen-enriched air, to an ozone generator. The resultant ozone-containing gas is introduced into a container, a treatment vessel, or the like containing the fibrous carbon nanostructures, to perform the ozone treatment. For example, the ozone treatment may be performed by generating, in a treatment vessel containing a dispersion liquid obtained by dispersing the fibrous carbon nanostructures as a surface treatment target in a suitable solvent, a reaction site through supply of ozone so that the ozone concentration in the treatment vessel is 0.3 mg/l to 20 mg/1, and performing reaction at a temperature of 0° C. to 80° C. typically for 1 min to 100 hr.

Various conditions such as the ozone concentration in the ozone-containing gas, the exposure time, and the exposure temperature may be set as appropriate based on the desired oxygen element content at the surfaces of the surface-treated fibrous carbon nanostructures.

<<Thickness of Electromagnetic Wave Shield Layer>>

The thickness of the electromagnetic wave shield layer is preferably 500 μm or less, more preferably 200 μm or less, and further preferably 120 μm or less, and is preferably 1 μm or more, and more preferably 8 μm or more. If the thickness of the electromagnetic wave shield layer is not less than the foregoing lower limit, in particular the distance by which incident electromagnetic waves pass in the electromagnetic wave shield layer increases and electromagnetic waves reached the inside of the electromagnetic wave shield layer are multiple-reflected, so that the electromagnetic wave absorption performance in an extremely high frequency band can be further enhanced. If the thickness of the electromagnetic wave shield layer is not more than the foregoing upper limit, the electromagnetic wave shield layer can be thinned while ensuring favorable electromagnetic wave shield performance and electromagnetic wave absorption performance, which contributes to higher versatility.

The thickness of the electromagnetic wave shield layer can be adjusted, for example, by appropriately changing the amounts of the surface-treated fibrous carbon nanostructures and the other components used in the below-described step (A).

<Another Constituent Member>

Examples of another constituent member that can be included in the electromagnetic wave shield structure according to the present disclosure besides the electromagnetic wave shield layer include an insulating support layer. For example, the electromagnetic wave shield structure according to the present disclosure may have a structure in which another constituent member such as an insulating support layer is directly or indirectly adhered to the electromagnetic wave shield layer. The electromagnetic wave shield structure that further includes another constituent member such as an insulating support layer directly or indirectly adhered to the electromagnetic wave shield layer has durability, while ensuring high electromagnetic wave shield performance and electromagnetic wave absorption performance in an extremely high frequency band. Such an electromagnetic wave shield structure can be thinned more easily, and handled more easily.

In the case where the electromagnetic wave shield structure according to the present disclosure further includes an insulating support layer as another constituent member, for example, the insulating support layer may be located at the outermost surface on the electromagnetic wave incidence side or at the outermost surface on the side opposite to the electromagnetic wave incidence side. As a result of providing the insulating support layer in this way, the durability of the electromagnetic wave shield structure can be further improved while fully utilizing high electromagnetic wave shield performance and electromagnetic wave absorption performance of the electromagnetic wave shield layer.

<<Insulating Support Layer>>

### [Insulating Material]

The insulating material forming the insulating support layer is not limited, and, for example, known resins and fillers may be used depending on the use of the electromagnetic wave shield structure. Specifically, for example, a resin having insulating property may be used alone, or an insulating material obtained by mixing a resin having insulating property with an optional filler having insulating property may be used. In the case where the electromagnetic wave shield structure according to the present disclosure further includes the insulating support layer, the insulating support layer preferably contains at least a resin having insulating property, in terms of imparting favorable flexibility and durability to the structure.

In the present disclosure, a substance having “insulation property” such as an insulating support layer or an insulating material preferably has a volume resistivity measured in accordance with JIS K 6911 of 10¹¹ Ω·cm or more.

In the present disclosure, rubbers and elastomers are included in “resin”.

—Resin—

Examples of the resin as the base material include natural rubber including epoxidized natural rubber, diene-based synthetic rubber (butadiene rubber, epoxidized butadiene rubber, styrene-butadiene rubber, (hydrogenated) acrylonitrile-butadiene rubber, ethylene vinyl acetate rubber, chloroprene rubber, vinylpyridine rubber, butyl rubber, chlorobutyl rubber, polyisoprene rubber), ethylene-propylene rubber, acrylic rubber, silicone rubber, epichlorohydrin rubber, urethane rubber, polysulfide rubber, fluororesin, urea resin, melamine resin, phenol resin, cellulosic resin (cellulose acetate, cellulose nitrate, cellulose acetate butyrate, etc.), casein plastic, soybean protein plastic, benzoguanamine resin, epoxy-based resin (bisphenol A-type epoxy resin, novolak-type epoxy resin, polyfunctionalized epoxy resin, alicyclic epoxy resin, etc.), diallyl phthalate resin, alkyd resin, polyvinyl chloride resin, polyethylene resin, polypropylene resin, styrene-based resin (ABS (acrylonitrile-butadiene-styrene) resin, AS (acrylonitrile-styrene) resin, polystyrene, etc.), acrylic resin, methacrylic resin, organic acid vinyl ester-based resin such as polyvinyl acetate, vinyl ether resin, halogen-containing resin, polycycloolefin resin, olefin resin, alicyclic olefin resin, polycarbonate resin, polyester resin including unsaturated polyester resin, polyamide resin, thermoplastic and thermosetting polyurethane resin, polysulfone resin, polyphenylene ether resin including modified polyphenylene ether resin, silicone resin, polyacetal resin, polyimide resin, polyethylene terephthalate resin, polybutylene terephthalate resin, polyarylate resin, polyphenylene sulfide resin, and polyether ether ketone resin. One of these resins may be used individually, or two or more of these resins may be used as a mixture.

Of these, the resin contained in the insulating support layer is preferably polyimide resin having excellent electrical insulating property and high strength and heat resistance.

—Insulating Filler—

The filler having insulating property (insulating filler) is not limited, and an insulating filler such as a known inorganic filler or organic filler may be used. Examples of the insulating filler include silica, talc, clay, titanium oxide, nylon fiber, vinylon fiber, acrylic fiber, and rayon fiber. One of these fillers may be used individually, or two or more of these fillers may be used as a mixture.

<Adhesion Method>

The method of directly adhering electromagnetic wave shield layers to each other and/or an electromagnetic wave shield layer and another constituent member such as an insulating support layer in the electromagnetic wave shield structure is not limited, and may be a hot laminating processing method, a drying method, or the like. With the hot laminating processing method, for example, the objects can be directly laminated and adhered using adhesive power by the insulating support layer component and the like dissolved at high temperature. With the drying method, for example, a liquid composition for forming an electromagnetic wave shield layer is applied onto another constituent member such as an insulating support layer and dried by any method, thus directly laminating and adhering the electromagnetic wave shield layer and the like while forming the electromagnetic wave shield layer. The liquid composition may be dried by performing natural drying, hot air drying, reduced pressure drying, or the like singly or in any combination.

The method of indirectly adhering electromagnetic wave shield layers to each other and/or an electromagnetic wave shield layer and another constituent member such as an insulating support layer in the electromagnetic wave shield structure may be, for example, a cold laminating processing method using an adhesive. With the cold laminating processing method, for example, any adhesive is applied to the surface of an electromagnetic wave shield layer or another constituent member such as an insulating support layer obtained by any method beforehand, and pressure is applied to indirectly laminate and adhere the objects through the adhesive. For example, the adhesive may have the same component as the insulating support layer. The electromagnetic wave shield layer can be formed, for example, by filtering a liquid composition for forming the electromagnetic wave shield layer.

<<Thickness of Electromagnetic Wave Shield Structure>>

The thickness of the electromagnetic wave shield structure is preferably in the same range as the foregoing suitable thickness of the electromagnetic wave shield layer, in the case where the electromagnetic wave shield structure is a single electromagnetic wave shield layer.

Even in the case where the electromagnetic wave shield structure includes a plurality of electromagnetic wave shield layers without an insulating support layer, the thickness of the electromagnetic wave shield structure (i.e. the total thickness of the laminated electromagnetic wave shield layers) is preferably in the same range as the foregoing suitable thickness of the electromagnetic wave shield layer.

In the case where the electromagnetic wave shield structure includes the electromagnetic wave shield layer and another constituent member such as an insulating support layer, the thickness of the electromagnetic wave shield structure is preferably 500 μm or less, more preferably 200 μm or less, further preferably 120 μm or less, and even more preferably 100 μm or less, and is preferably 1 μm or more, more preferably 10 μm or more, and further preferably 25 μm or more. If the thickness of the electromagnetic wave shield structure is not less than the foregoing lower limit, the electromagnetic wave absorption performance of the electromagnetic wave shield layer in an extremely high frequency band can be further enhanced for the foregoing reason, and also the durability and the free-standing ability as a structure can be further improved. If the thickness of the electromagnetic wave shield structure is not more than the foregoing upper limit, the electromagnetic wave shield structure can be thinned while mainly ensuring favorable electromagnetic wave shield performance and electromagnetic wave absorption performance of the electromagnetic wave shield layer, which contributes to higher versatility as a structure.

(Production Method for Electromagnetic Wave Shield Structure)

The production method for an electromagnetic wave shield structure according to the present disclosure is a method of producing any of the foregoing electromagnetic wave shield structures, and includes a step (A) of forming an electromagnetic wave shield layer that has a weight per unit area (mass per unit area) in a predetermined range, using surface-treated fibrous carbon nanostructures obtained by treating surfaces of fibrous carbon nanostructures, wherein the step (A) includes: a step (A-2) of dispersing the surface-treated fibrous carbon nanostructures in a solvent to obtain a dispersion liquid; and a step (A-3) of removing the solvent from the dispersion liquid to form the electromagnetic wave shield layer. In addition to the steps (A-2) and (A-3), the step (A) in the production method for an electromagnetic wave shield structure according to the present disclosure may further include, for example, another step such as a step (A-1) of subjecting the surfaces of the fibrous carbon nanostructures to plasma treatment and/or ozone treatment to obtain the surface-treated fibrous carbon nanostructures. Since the electromagnetic wave shield structure yielded by the production method for an electromagnetic wave shield structure according to the present disclosure is formed by removing the solvent from the predetermined dispersion liquid, for example, the electromagnetic wave shield structure can deliver excellent electromagnetic wave shield performance and electromagnetic wave absorption performance for millimeter waves of 30 GHz or more, and favorably shield electromagnetic wave noise components.

<Step (A)>

In the step (A), the electromagnetic wave shield layer having a weight per unit area of 0.5 g/m² or more and 30 g/m² or less is formed using the surface-treated fibrous carbon nanostructures obtained by treating the surfaces of the fibrous carbon nanostructures. In the step (A), the electromagnetic wave shield layer is formed through the step (A-2) of obtaining the dispersion liquid and the step (A-3) of removing the solvent from the dispersion liquid to form the electromagnetic wave shield layer. The step (A) may further include, for example, the step (A-1) of obtaining the surface-treated fibrous carbon nanostructures before the steps (A-2) and (A-3). As a result of removing the solvent from the dispersion liquid and forming the electromagnetic wave shield layer having predetermined components with the predetermined mass per unit area in this way, the uniformity of the electromagnetic wave shield layer can be increased, and the electromagnetic wave shield performance and the electromagnetic wave absorption performance of the electromagnetic wave shield structure in an extremely high frequency band can be further enhanced.

<<Step (A-1)>>

In the optional step (A-1), the surfaces of the fibrous carbon nanostructures are subjected to plasma treatment and/or ozone treatment to obtain the surface-treated fibrous carbon nanostructures. Thus, in the step (A-1), the surface-treated fibrous carbon nanostructures may be obtained by plasma treatment, by ozone treatment, or by a combination of plasma treatment and ozone treatment.

Suitable conditions of plasma treatment and ozone treatment used here may be the same as the suitable conditions of plasma treatment and ozone treatment described above in the paragraphs for the electromagnetic wave shield layer.

<<Step (A-2)>>

In the step (A-2), the surface-treated fibrous carbon nanostructures are dispersed in the solvent to obtain the dispersion liquid. When obtaining the dispersion liquid in the step (A-2), for example, optional other components besides the surface-treated fibrous carbon nanostructures, such as resins and additives, may be further dispersed in the solvent.

The fibrous carbon nanostructures may be a commercial product, or fibrous carbon nanostructures prepared by the same method as the method of preparing fibrous carbon nanostructures described above in the paragraphs for the electromagnetic wave shield layer. Suitable types, properties, and preparation methods of the fibrous carbon nanostructures and the surface-treated fibrous carbon nanostructures may be the same as the suitable conditions of the fibrous carbon nanostructures and the surface-treated fibrous carbon nanostructures described above in the paragraphs for the electromagnetic wave shield layer.

The method of treating the surfaces of the fibrous carbon nanostructures may be, for example, a surface treatment method according to the step (A-1).

The other components that can be used optionally are not limited, and may be the same known additives as the other components described above in the paragraphs for the electromagnetic wave shield layer. Examples include surfactants such as sodium dodecylsulfonate, sodium deoxycholate, sodium cholate, and sodium dodecylbenzenesulfonate as examples of dispersants typically used in the preparation of dispersion liquids. One of these additives may be used individually, or two or more of these additives may be used as a mixture. The other components may also be the same known resins as those described above as examples of resin as the base material of the insulating material.

Such resins and additives may be added to the solvent in any amounts at any timings within the range in which the dispersibility of the surface-treated fibrous carbon nanostructures is not impaired. For example, the amounts of the other components can be determined depending on the content proportion of the other components described above in the paragraphs for the electromagnetic wave shield layer.

[Solvent]

The solvent is not limited. Examples of solvents that can be used include: water; alcohols such as methanol, ethanol, n-propanol, isopropanol, n-butanol, isobutanol, t-butanol, pentanol, hexanol, heptanol, octanol, nonanol, and decanol; ketones such as acetone, methyl ethyl ketone, and cyclohexanone; esters such as ethyl acetate and butyl acetate; ethers such as diethyl ether, dioxane, and tetrahydrofuran; amide-based polar organic solvents such as N,N-dimethylformamide and N-methylpyrrolidone; and aromatic hydrocarbons such as toluene, xylene, chlorobenzene, ortho-dichlorobenzene, and para-dichlorobenzene. One of these solvents may be used individually, or two or more of these solvents may be used as a mixture. Of these, methyl ethyl ketone is preferable as the solvent, in terms of favorably dispersing the surface-treated fibrous carbon nanostructures.

[Dispersion Method]

The method of dispersing the surface-treated fibrous carbon nanostructures in the solvent is not limited, and may be a typical dispersion method using a conventionally known dispersion device. In terms of enhancing the dispersibility of the surface-treated fibrous carbon nanostructures, it is preferable to prepare the dispersion liquid by dispersion treatment that brings about a cavitation effect or dispersion treatment that brings about a crushing effect described in detail below. Prior to dispersion treatment, the surface-treated fibrous carbon nanostructures may be preliminary-dispersed in the solvent using a stirrer or the like.

—Dispersion Treatment that Brings about Cavitation Effect—

The dispersion treatment that brings about a cavitation effect is a dispersion method that utilizes shock waves caused by the rupture of vacuum bubbles formed in water when high energy is applied to the liquid. This dispersion method can be used to favorably disperse the surface-treated fibrous carbon nanostructures. The dispersion treatment that brings about a cavitation effect is more preferably performed at a temperature of 50° C. or less. This suppresses a change in concentration due to solvent volatilization.

Specific examples of the dispersion treatment that brings about a cavitation effect include dispersion treatment using ultrasound, dispersion treatment using a jet mill, and dispersion treatment using high-shear stirring. One of these dispersion treatments may be carried out or a plurality of these dispersion treatments may be carried out in combination. More specifically, an ultrasonic homogenizer, a jet mill, and a high-shear stirring device are preferably used for the dispersion treatment that brings about a cavitation effect. Commonly known conventional devices may be used as these devices.

In a situation in which an ultrasonic homogenizer is used, the preliminary dispersion liquid or the mixed solution before the dispersion is irradiated with ultrasound by the ultrasonic homogenizer. The irradiation time may be set as appropriate in consideration of the concentration and dispersion degree of surface-treated fibrous carbon nanostructures and so forth.

In a situation in which a jet mill is used, conditions are set as appropriate in consideration of the concentration and dispersion degree of surface-treated fibrous carbon nanostructures and so forth. For example, the number of treatment repetitions is preferably 1 to 100. Furthermore, the pressure is preferably 20 MPa to 250 MPa, and the temperature is preferably 15° C. to 50° C. An example of a suitable jet mill is a high-pressure wet jet mill. Specific examples encompass “Nanomaker®” (Nanomaker is a registered trademark in Japan, other countries, or both) (manufactured by Advanced Nano Technology Co., Ltd.), “Nanomizer” (manufactured by Nanomizer Inc.), “NanoVater” (manufactured by Yoshida Kikai Co. Ltd.), and “Nano Jet Pal®” (Nano Jet Pal is a registered trademark in Japan, other countries, or both) (manufactured by Jokoh Co., Ltd.).

In a situation in which high-shear stirring is used, the preliminary dispersion liquid or the mixed solution before the dispersion is subjected to stirring and shearing using a high-shear stirring device. The rotational speed is preferably as fast as possible. The operating time (i.e., the time during which the device is rotating) is preferably 3 min to 4 hr, the circumferential speed is preferably 20 m/s to 50 m/s, and the temperature is preferably 15° C. to 50° C. Examples of a high-shear stirring device encompass: stirrers typified by “Ebara Milder” (manufactured by Ebara Corporation), “CAVITRON” (manufactured by Eurotec Co., Ltd.), and “DRS2000” (manufactured by Ika Works, Inc.); stirrers typified by “CLEARMIX® CLM-0.8S” (CLEARMIX is a registered trademark in Japan, other countries, or both) (manufactured by M Technique Co., Ltd.); turbine-type stirrers typified by “T. K. Homo Mixer” (manufactured by Tokushu Kika Kogyo Co., Ltd.); and stirrers typified by “TK Fillmix” (manufactured by Tokushu Kika Kogyo Co., Ltd.).

—Dispersion Treatment that Brings about Crushing Effect—

The dispersion treatment that brings about a crushing effect uniformly disperses the surface-treated fibrous carbon nanostructures in the solvent by causing crushing and dispersion of the surface-treated fibrous carbon nanostructures by imparting shear force to the preliminary dispersion liquid or the mixed solution before the dispersion and by further applying back pressure to the preliminary dispersion liquid or the mixed solution before the dispersion, while cooling the preliminary dispersion liquid or the mixed solution before the dispersion as necessary in order to reduce air bubble formation. The dispersion treatment that brings about a crushing effect is even more advantageous because, in addition to enabling uniform dispersion of the surface-treated fibrous carbon nanostructures, dispersion treatment that brings about a crushing effect reduces damage to the surface-treated fibrous carbon nanostructures due to shock waves when air bubbles burst compared to the above-mentioned dispersion treatment that brings about a cavitation effect. The dispersion treatment that brings about a crushing effect is also advantageous because adhesion of air bubbles to the surface-treated fibrous carbon nanostructures and energy loss due to the generation of air bubbles can be suppressed, and the surface-treated fibrous carbon nanostructures can also be effectively dispersed evenly.

The back pressure may be applied to the preliminary dispersion liquid or the mixed solution before the dispersion by applying a load to the flow of the preliminary dispersion liquid or the mixed solution before the dispersion. For example, a desired back pressure may be applied to the preliminary dispersion liquid or the mixed solution before the dispersion by providing a multiple step-down device downstream from the disperser. When applying the back pressure to the preliminary dispersion liquid or the mixed solution before the dispersion, the back pressure may be applied by lowering pressure at once to atmospheric pressure, yet the pressure is preferably lowered over multiple steps. With this multiple step-down device, the back pressure is lowered over multiple steps, so that when the surface-treated fibrous carbon nanostructures are ultimately released into atmospheric pressure, the occurrence of air bubbles in the dispersion liquid can be suppressed.

These types of dispersion treatment may be performed singly or in any combination.

In particular, as dispersion treatment in the preparation of the dispersion liquid containing the surface-treated fibrous carbon nanostructures, dispersion treatment that uses a dispersion treatment device including a thin-tube flow path and transfers the preliminary dispersion liquid to the thin-tube flow path to apply shear force to the preliminary dispersion liquid and thereby disperse the fibrous carbon nanostructures is preferable. By transferring the preliminary dispersion liquid to the thin-tube flow path and applying shear force to the preliminary dispersion liquid to disperse the fibrous carbon nanostructures, the fibrous carbon nanostructures can be dispersed favorably while preventing damage to the fibrous carbon nano structures.

Examples of a dispersion system having the above structure include the product name “BERYU SYSTEM PRO” (manufactured by BeRyu Corporation). Dispersion treatment that brings about a crushing effect may be performed by using such a dispersion system and appropriately controlling the dispersion conditions.

<<Step (A-3)>>

In the step (A-3), the solvent is removed from the dispersion liquid obtained as described above, to form the electromagnetic wave shield layer. The method of removing the solvent from the dispersion liquid is not limited, and may be a known method. In terms of easily forming a uniform electromagnetic wave shield layer, a method of filtering and/or drying the dispersion liquid is preferable. Typically, the electromagnetic wave shield layer formed in this way serves as the electromagnetic wave shield structure.

[Filtering]

In the step (A-3), it is preferable to filter the dispersion liquid to remove the solvent and form the electromagnetic wave shield layer. Particularly in the case of forming the electromagnetic wave shield layer alone without laminating it with another constituent member described later in order to obtain the electromagnetic wave shield layer as a single film, it is preferable to remove the solvent in the dispersion liquid by filtering in terms of ease of production.

Filtering types include natural filtering, reduced pressure filtering, pressure filtering, and centrifugal filtering. In terms of promptly forming the electromagnetic wave shield layer without damaging the surface-treated fibrous carbon nanostructures in the electromagnetic wave shield layer, reduced pressure filtering is preferable. As a filter medium, a porous material such as a glass fiber filter, a membrane filter, or a filter plate having a desired pore size that enables favorable separation of the surface-treated fibrous carbon nanostructures may be used. Various filtering conditions such as time, pressure, and rotation frequency are not limited as long as the resultant electromagnetic wave shield layer has a predetermined mass per unit area, and may be selected as appropriate depending on the desired properties of the electromagnetic wave shield layer.

The electromagnetic wave shield layer obtained by filtering the dispersion liquid has the surface-treated fibrous carbon nanostructures approximately uniformly dispersed therein without being damaged, and is formed with the predetermined mass per unit area. Such an electromagnetic wave shield layer can deliver better electromagnetic wave shield performance and electromagnetic wave absorption performance in an extremely high frequency band.

[Drying]

In the step (A-3), it is also preferable that, instead of or in addition to the filtering, the dispersion liquid is dried to remove the solvent and form the electromagnetic wave shield layer. When performing the drying in addition to the filtering, the drying preferably follows the filtering. Particularly in the case of laminating the electromagnetic wave shield layer with optional another constituent member such as an insulating support layer in order to obtain a laminated film of the electromagnetic wave shield layer and the other constituent member, it is preferable to apply the dispersion liquid onto the other constituent member by a known technique and dry and remove the solvent, in terms of ease of production.

Drying method types include natural drying, hot air drying, and reduced pressure drying, which may be performed singly or in combination. In terms of promptly forming the electromagnetic wave shield layer without damaging the surface-treated fibrous carbon nanostructures in the electromagnetic wave shield layer, reduced pressure drying is preferable. Various drying conditions such as time, temperature, and pressure are not limited as long as the resultant electromagnetic wave shield layer has a predetermined mass per unit area, and may be selected as appropriate depending on the desired properties of the electromagnetic wave shield layer.

The electromagnetic wave shield layer obtained by drying the dispersion liquid has the surface-treated fibrous carbon nanostructures approximately uniformly dispersed therein without being damaged, and is formed with the predetermined mass per unit area. Such an electromagnetic wave shield layer can deliver better electromagnetic wave shield performance and electromagnetic wave absorption performance in an extremely high frequency band.

Only one of the filtering and the drying may be performed. Alternatively, both the filtering and the drying may be performed in such a manner that, for example, a coarse film is formed by filtering and then the layer is formed by drying. It is preferable to perform both the filtering and the drying.

<Other Steps>

Other steps that can be optionally included in the production method for an electromagnetic wave shield structure according to the present disclosure are not limited, and examples include: a step of preparing another constituent member such as an insulating support layer described above in the paragraphs for the electromagnetic wave shield structure; a step of adhering the other constituent member and the electromagnetic wave shield layer; and a step of adjusting the shape of the formed electromagnetic wave shield layer.

<<Step of Preparing Other Constituent Member>>

In the step of preparing another constituent member, for example, optional another constituent member same as another constituent member such as an insulating support layer described above in the paragraphs for the electromagnetic wave shield structure can be prepared. In the preparation of the other constituent member, a commercial product may be purchased. In the case where the other constituent member is an insulating support layer, for example, the other constituent member may be formed by a known method using the insulating material described above in the paragraphs for the electromagnetic wave shield structure.

<<Adhesion Step>>

In the step of adhering the other constituent member and the electromagnetic wave shield layer, for example, the same direct adhesion method or indirect adhesion method as the adhesion method described above in the paragraphs for the electromagnetic wave shield structure may be used.

In the case of not directly forming the electromagnetic wave shield layer on the other constituent member, for example, an adhesive made of the same component as the component of the other constituent member may be used in the lamination of the electromagnetic wave shield layer and the other constituent member. When laminating the electromagnetic wave shield layer and an insulating support layer as the other constituent member, the insulating support layer is preferably located at the outermost surface on the side opposite to the electromagnetic wave incidence side. As a result of providing the insulating support layer in this way, the durability of the electromagnetic wave shield structure can be further improved while fully utilizing high electromagnetic wave shield performance and electromagnetic wave absorption performance of the electromagnetic wave shield layer.

<<Shape Adjustment Step>>

In the step of adjusting the shape of the electromagnetic wave shield layer, for example, the formed electromagnetic wave shield layer can be adjusted to a desired shape using a punching machine, an extruder, an injection machine, a compressor, a roller, or the like after the step (A).

### EXAMPLES

The following will provide a more specific description of the present disclosure based on examples. However, the present disclosure is not limited to the following examples. In the following description, “%” used in expressing quantities is by mass, unless otherwise specified.

In Examples and Comparative Examples, the following methods were used in order to measure and evaluate the BET specific surface area and average fiber diameter of the fibrous carbon nanostructures, the amount of the oxygen element and the amount of the nitrogen element at the surfaces of the surface-treated fibrous carbon nanostructures, the mass per unit area and thickness of the electromagnetic wave shield layer, and the electromagnetic wave absorption performance and electromagnetic wave shield performance of the electromagnetic wave shield structure.

<BET Specific Surface Area>

The BET specific surface area of the fibrous carbon nanostructures was measured as follows.

A cell for dedicated use in a fully automated specific surface area analyzer (manufactured by Mountech Co., Ltd., product name “Macsorb® HM model-1210” (Macsorb is a registered trademark in Japan, other countries, or both)) was thermally treated at a temperature of 110° C. for 5 hr or more to be sufficiently dried. Into the cell was put 20 mg of fibrous carbon nanostructures measured on a scale. The cell was then placed at a predetermined location of the analyzer, and the BET specific surface area was automatically measured.

The analyzer measures a specific surface area on a principle that it finds an adsorption and desorption isotherm of liquid nitrogen at 77K and measures the specific surface area from the adsorption and desorption isotherm according to Brunauer-Emmett-Teller (BET) method.

<Average Fiber Diameter>

The average fiber diameter of the fibrous carbon nanostructures was measured as follows.

0.1 mg of the fibrous carbon nanostructures and 3 ml of ethanol were measured in a 10-ml screw tube bottle on a scale. Next, an ultrasonic cleaner (manufactured by Branson Ultrasonics Corporation, product name “5510J-DTH”) carried out an ultrasonic treatment with respect to the fibrous carbon nanostructures and the ethanol in the screw tube bottle with a vibration output of 180 W at a temperature of 10° C. to 40° C. for 30 min so that the fibrous carbon nanostructures were uniformly dispersed in the ethanol. A dispersion liquid for fiber diameter measurement was thus obtained. Then, 50 μl of the obtained dispersion liquid for fiber diameter measurement was dropped on a micro grid (manufactured by Okenshoji Co., Ltd., product name “Micro Grid Type A STEM 150 Cu grid”) for use in a transmission electron microscope, left to stand for 1 hr or more, and then dried in a vacuum at a temperature of 25° C. for 5 hr or more, to cause the fibrous carbon nanostructures to be held by the micro grid. The micro grid holding the fibrous carbon nanostructures was then placed on a transmission electron microscope (manufactured by Topcon Technohouse Corporation, product name “EM-002B”). The fibrous carbon nanostructures were observed at 1.5 million magnifications.

The fibrous carbon nanostructures were observed at ten random places of the micro grid. Ten fibrous carbon nanostructures were selected at random at each of the ten random places, and the diameter of each of the fibrous carbon nanostructures in the direction in which the diameter was shortest was measured. A number-average diameter value of measured diameters of 100 fibrous carbon nanostructures was found as the average fiber diameter (nm) of the fibrous carbon nanostructures.

The average fiber diameter measured as described above was maintained also as the average fiber diameter of the surface-treated fibrous carbon nanostructures.

<Amount of Oxygen Element and Amount of Nitrogen Element>

The amount of the oxygen element (oxygen element content) and the amount of the nitrogen element (nitrogen element content) at the surfaces of the surface-treated fibrous carbon nanostructures were measured as follows.

Each of the amount of the oxygen element and the amount of the nitrogen element relative to the amount of the carbon element (carbon element content) at the surfaces of the surface-treated fibrous carbon nanostructures was calculated. Specifically, the surface-treated fibrous carbon nanostructures were fixed to a carbon double sided tape, to produce a test piece. The test piece was then irradiated with 150 W (acceleration voltage: 15 kV, current value: 10 mA) AlKa monochromator X rays by an X-ray photoelectron spectrometer (XPS, manufactured by KRATOS Co., product name “AXIS ULTRA DLD”). At angle 0=90° of the test piece surface with the detector direction, a wide spectrum was measured for qualitative analysis, and then a narrow spectrum of each element was measured for quantitative analysis. With use of an analysis application (manufactured by KRATOS Co., product name “Vision Processing”), a peak area was integrated from the obtained spectra. By correction using an element-specific sensitivity coefficient, how many times each of the amount of the oxygen element and the amount of the nitrogen element was relative to the amount of the carbon element was calculated.

For Comparative Examples not subjected to surface treatment, the oxygen element content and the nitrogen element content at the surfaces of the fibrous carbon nanostructures were measured by the same method as above.

<Mass Per Unit Area>

The mass per unit area (g/m²) of the electromagnetic wave shield layer in the electromagnetic wave shield structure was measured according to the following Formula (1):

Mass per unit area=weight (g) of electromagnetic wave shield layer after drying/area (m²) of electromagnetic wave shield layer after drying (1).

<Thickness>

The thickness of the electromagnetic wave shield layer was measured as follows.

A micrometer (manufactured by Mitutoyo Corporation, product name “293 series, MDH-25”) was used to measure thickness at ten points for the electromagnetic wave shield layer, and a number-average value of the measurements was taken to be the thickness (μm) of the electromagnetic wave shield layer.

In the case where the electromagnetic wave shield structure in which the electromagnetic wave shield layer was formed on the insulating support layer was produced, first the total thickness of the electromagnetic wave shield structure was measured by the same method as above, and then the thickness of the insulating support layer was subtracted from the total thickness to find the thickness (μm) of the electromagnetic wave shield layer.

<Electromagnetic Wave Absorption Performance>

The electromagnetic wave absorption performance of the electromagnetic wave shield structure was evaluated by measuring the incident electromagnetic wave reflection attenuation amount (dB). Herein, “reflection attenuation amount” refers to a decrease in the actual reflection amount with respect to the reflection amount when an incident electromagnetic wave undergoes total reflection, and corresponds to the electromagnetic wave absorption amount in which the electromagnetic wave is absorbed inside the electromagnetic wave shield structure.

Specifically, a conductive metal plate was attached to one side of the produced electromagnetic wave shield structure as a specimen. The side to which the conductive metal plate was attached was any one side of the electromagnetic wave shield layer in Examples 1 to 5 and Comparative Examples 2 and 3, and the insulating support layer side in Examples 6 and 7 and Comparative Examples 1, 4, and 5. The electromagnetic wave shield structure was then placed in a measurement system (manufactured by KEYCOM Co., Ltd., product name “Model No. DPS10”) so that electromagnetic waves were incident on the side of the electromagnetic wave shield structure to which the conductive metal plate was not attached. Following this, the measurement system, a vector network analyzer (manufactured by Anritsu Corporation, “ME7838A”), and an antenna (part number “RH15S10” and “RH10S10”) were used to measure S (Scattering) parameter (S11) with one port by the free space method at frequencies from 60 GHz to 90 GHz.

Table 1 shows the reflection attenuation amount (dB) calculated according to the following Formula (2) based on S11 parameter when irradiating electromagnetic waves of frequencies of 60 GHz, 75 GHz, and 90 GHz. A higher reflection attenuation amount indicates better electromagnetic wave absorption performance.

Reflection attenuation amount (dB)=20 log|S11| (2).

<Electromagnetic Wave Shield Performance>

The electromagnetic wave shield performance of the electromagnetic wave shield structure was evaluated by measuring the incident electromagnetic wave transmission attenuation amount (dB). Herein, “transmission attenuation amount” refers to a decrease in the actual transmission amount with respect to the transmission amount when an incident electromagnetic wave is all transmitted through the electromagnetic wave shield structure, and corresponds to the sum of the electromagnetic wave absorption amount in which the electromagnetic wave is absorbed inside the electromagnetic wave shield structure and the electromagnetic wave reflection amount in which the electromagnetic wave is reflected on the surface of the electromagnetic wave shield structure.

Specifically, S21 parameter was measured for the produced electromagnetic wave shield structure under the same conditions as the measurement of the electromagnetic wave absorption performance described above.

Table 1 shows the transmission attenuation amount (dB) calculated according to the following Formula (3) based on S21 parameter when irradiating electromagnetic waves of frequencies of 60 GHz, 75 GHz, and 90 GHz. A higher transmission attenuation amount indicates better electromagnetic wave shield performance.

Transmission attenuation amount (dB)=20 log|S21| (3).

### Example 1

<Formation of Electromagnetic Wave Shield Layer>

In the formation of the electromagnetic wave shield layer, first, a liquid composition (dispersion liquid) used to form the electromagnetic wave shield layer was prepared. The solvent was then removed from the dispersion liquid, thus forming the electromagnetic wave shield layer. In the preparation of the dispersion liquid, first, fibrous carbon nanostructures were prepared. Surface-treated fibrous carbon nanostructures obtained by treating the surfaces of the prepared fibrous carbon nanostructures were used.

[Preparation of Fibrous Carbon Nanostructures]

Carbon nanotubes (SGCNTs) were prepared by the super growth method described in JP 4,621,896 B2 and taken to be the fibrous carbon nanostructures. Specifically, SGCNTs were prepared on the following conditions:
Carbon compound: ethylene (feeding rate: 50 sccm)
Atmosphere (gas) (Pa): mixed gas of helium and hydrogen (feeding rate: 1000 sccm)
Pressure: 1 atmospheric pressure
Amount of water vapor added: 300 ppm
Reaction temperature: 750° C.
Reaction time: 10 min
Metal catalyst: iron thin film of 1 nm in thickness
Substrate: silicon wafer.

Upon measuring the resultant SGCNTs as the fibrous carbon nanostructures with a Raman spectrometer, spectra of a Radial Breathing Mode (RBM) were observed in a low-wavenumber region of 100 cm⁻¹ to 300 cm⁻¹, which is characteristic of single-walled carbon nanotubes. Through observation of the resultant SGCNTs under a transmission electron microscope, it was confirmed that 99% or more were single-walled carbon nanotubes (hereafter also referred to as “SWCNTs”) (the prepared SGCNTs are hereafter referred to as “SWCNTs”). As a result of evaluating the properties of the resultant SWCNTs according to the foregoing methods, the BET specific surface area was 880 m²/g, the average fiber diameter was 3.3 nm, and the average fiber length was 100 μm or more. The results are partly shown in Table 1.

[Preparation of Surface-Treated Fibrous Carbon Nanostructures]

### —Plasma Treatment—

The SWCNTs obtained as described above were treated for 0.5 hr under conditions of pressure: 40 Pa, power: 200 W (energy output per unit area: 1.28 W/cm²), rotational speed: 30 rpm, and air introduction using a gas introducible reduced pressure plasma device (manufactured by SAKIGAKE-Semiconductor Co., Ltd., product name “YHS-DOS”), to obtain surface-treated fibrous carbon nanostructures (surface-treated SWCNTs).

The oxygen element content (times) and the nitrogen element content (times) relative to the carbon element content at the surfaces of the surface-treated SWCNTs were each determined according to the foregoing method. The results are shown in Table 1.

[Preparation of Dispersion Liquid]

The surface-treated SWCNTs obtained as described above were added to methyl ethyl ketone as an organic solvent so as to have a concentration of 0.2%, and stirred with a magnetic stirrer for 24 hr to obtain a preliminary dispersion liquid of the surface-treated SWCNTs.

Next, the preliminary dispersion liquid was charged into a multistage step-down high-pressure homogenizer (manufactured by Beryu Corporation, product name “BERYU SYSTEM PRO”) having a multistage pressure controller (multistage step-down transformer) connected to a high-pressure dispersion treatment portion (jet mill) having a thin-tube flow path portion with a diameter of 200 μm. A pressure of 120 MPa was applied to the charged preliminary dispersion liquid intermittently and instantaneously, to perform a dispersion process once while transferring the preliminary dispersion liquid into the thin-tube flow path. A CNT dispersion liquid containing the surface-treated fibrous carbon nanostructures and the solvent was thus obtained.

[Formation of Electromagnetic Wave Shield Layer]

90 ml of the CNT dispersion liquid obtained as described above was filtered at 0.09 MPa using a reduced pressure filtering device including a porous membrane filter (pore size: 0.1 μm, diameter: 120 mm), to form a carbon coarse film. After the end of the filtering, 100 ml of methanol and 100 ml of water were caused to pass through the reduced pressure filtering device, to clean the carbon coarse film formed on the membrane filter. After the cleaning, air was caused to pass through the reduced pressure filtering device for 15 min. Following this, a laminated film of the cleaned carbon coarse film and membrane filter was immersed in ethanol, and then the carbon coarse film in a wet state was separated from the membrane filter and taken out. The taken carbon coarse film in a wet state was vacuum dried in a vacuum drier at a temperature of 100° C. for 24 hr to remove liquid content, thus obtaining a single electromagnetic wave shield layer. The content proportion of the surface-treated fibrous carbon nanostructures in the obtained electromagnetic wave shield layer was more than 99.9%.

According to the foregoing measurement method, the obtained electromagnetic wave shield layer was a free-standing film with a surface-treated fibrous carbon mass per unit area of 6.3 g/m² and a thickness of 22 μm. The area of the electromagnetic wave shield layer after drying used in the calculation of the mass per unit area can be determined from the diameter of the porous membrane filter. The results are shown in Table 1.

[Production of Electromagnetic Wave Shield Structure]

The obtained electromagnetic wave shield layer was taken to be an electromagnetic wave shield structure.

The electromagnetic wave absorption performance and the electromagnetic wave shield performance of the electromagnetic wave shield structure were measured and evaluated according to the foregoing methods.

The results are shown in Table 1.

### Example 2

Fibrous carbon nanostructures, surface-treated fibrous carbon nanostructures, a CNT dispersion liquid, an electromagnetic wave shield layer, and an electromagnetic wave shield structure were produced in the same way as in Example 1, except that the treatment time of plasma treatment under air introduction conditions was changed to 2 hr in the preparation of the surface-treated fibrous carbon nanostructures, and the amount of the CNT dispersion liquid used for the filtering was changed to 40 ml in the formation of the electromagnetic wave shield layer. The content proportion of the surface-treated fibrous carbon nanostructures in the obtained electromagnetic wave shield layer was more than 99.9%.

Measurement was performed in the same way as in Example 1. The results are shown in Table 1.

### Example 3

Fibrous carbon nanostructures, surface-treated fibrous carbon nanostructures, a CNT dispersion liquid, an electromagnetic wave shield layer, and an electromagnetic wave shield structure were produced in the same way as in Example 1, except that plasma treatment under air introduction conditions was replaced with plasma treatment under nitrogen introduction conditions in the preparation of the surface-treated fibrous carbon nanostructures, and the amount of the CNT dispersion liquid used for the filtering was changed to 240 ml in the formation of the electromagnetic wave shield layer. The content proportion of the surface-treated fibrous carbon nanostructures in the obtained electromagnetic wave shield layer was more than 99.9%.

Measurement was performed in the same way as in Example 1. The results are shown in Table 1.

### Example 4

Fibrous carbon nanostructures, surface-treated fibrous carbon nanostructures, a CNT dispersion liquid, an electromagnetic wave shield layer, and an electromagnetic wave shield structure were produced in the same way as in Example 1, except that plasma treatment under air introduction conditions was replaced with plasma treatment under nitrogen introduction conditions and the treatment time was changed to 2 hr in the preparation of the surface-treated fibrous carbon nanostructures, and the amount of the CNT dispersion liquid used for the filtering was changed to 400 ml in the formation of the electromagnetic wave shield layer. The content proportion of the surface-treated fibrous carbon nanostructures in the obtained electromagnetic wave shield layer was more than 99.9%.

Measurement was performed in the same way as in Example 1. The results are shown in Table 1.

### Example 5

Fibrous carbon nanostructures, surface-treated fibrous carbon nanostructures, a CNT dispersion liquid, an electromagnetic wave shield layer, and an electromagnetic wave shield structure were produced in the same way as in Example 1, except that plasma treatment under air introduction conditions was replaced with ozone treatment (described in detail below) and the treatment time was changed to 24 hr in the preparation of the surface-treated fibrous carbon nanostructures, and the amount of the CNT dispersion liquid used for the filtering was changed to 220 ml in the formation of the electromagnetic wave shield layer. The content proportion of the surface-treated fibrous carbon nanostructures in the obtained electromagnetic wave shield layer was more than 99.9%.

Measurement was performed in the same way as in Example 1. The results are shown in Table 1.

### —Ozone Treatment—

For SWCNTs obtained in the same way as in Example 1, a SWCNT dispersion liquid having methyl ethyl ketone as a solvent was produced, and placed in a treatment vessel of an ozone generator (manufactured by Asahi Techniglass Co., Ltd., product name “LABO OZON-250”). The SWCNT dispersion liquid was then treated for 24 hr while stirring it, with a temperature of 25° C. and an ozone concentration of 0.65 mg/l in the treatment vessel. Surface-treated SWCNTs were thus obtained.

### Example 6

Surface-treated fibrous carbon nanostructures, a CNT dispersion liquid, an electromagnetic wave shield layer, and an electromagnetic wave shield structure were produced in the same way as in Example 1, except that multi-walled carbon nanotubes (hereafter also referred to as “MWCNTs”) (manufactured by Nanocyl SA, product name “NC7000”, BET specific surface area: 265 m²/g, average fiber diameter: 10 nm, average fiber length: 1.5 μm) were used instead of the SWCNTs prepared as described above in the preparation of the fibrous carbon nanostructures, plasma treatment under air introduction conditions was replaced with ozone treatment (described in detail below) and the treatment time was changed to 48 hr in the preparation of the surface-treated fibrous carbon nanostructures, and a drying method (described in detail below) was used instead of the filtering in the formation of the electromagnetic wave shield layer. The content proportion of the surface-treated fibrous carbon nanostructures in the obtained electromagnetic wave shield layer was more than 99.9%.

Measurement was performed in the same way as in Example 1. The results are shown in Table 1.

### —Ozone Treatment—

For the foregoing MWCNTs, a MWCNT dispersion liquid having methyl ethyl ketone as a solvent was produced, and placed in a treatment vessel of an ozone generator (manufactured by Asahi Techniglass Co., Ltd., product name “LABO OZON-250”). The MWCNT dispersion liquid was then treated for 48 hr while stirring it, with a temperature of 25° C. and an ozone concentration of 0.65 mg/l in the treatment vessel. Surface-treated MWCNTs were thus obtained. [Formation of electromagnetic wave shield layer]

A polyimide film (manufactured by DuPont-Toray Co., Ltd., product name “Kapton® 100H Type” (Kapton is a registered trademark in Japan, other countries, or both), thickness: 25 μm) cut to a diameter of 120 mm as an insulating support layer was placed at the bottom of a stainless steel mold (diameter: 120 mm, height: 100 mm). 50 ml of the CNT dispersion liquid was charged into the mold in which the polyimide film was placed, from above the polyimide film. After the charging, the CNT dispersion liquid was natural dried for 48 hr or more. Subsequently, the mold was vacuum dried in a vacuum drier at a temperature of 100° C. for 24 hr to remove the solvent, thus simultaneously producing an electromagnetic wave shield layer formed on the polyimide film and an electromagnetic wave shield structure in which an electromagnetic wave shield layer was formed on the polyimide film. The area of the electromagnetic wave shield layer after drying used in the calculation of the mass per unit area can be determined from the diameter of the polyimide film.

### Example 7

Fibrous carbon nanostructures, surface-treated fibrous carbon nanostructures, a CNT dispersion liquid, an electromagnetic wave shield layer, and an electromagnetic wave shield structure were produced in the same way as in Example 1, except that a drying method (described in detail below) was used instead of the filtering in the formation of the electromagnetic wave shield layer. The content proportion of the surface-treated fibrous carbon nanostructures in the obtained electromagnetic wave shield layer was more than 99.9%.

Measurement was performed in the same way as in Example 1. The results are shown in Table 1.

### [Formation of Electromagnetic Wave Shield Layer]

A polyimide film (manufactured by DuPont-Toray Co., Ltd., product name “Kapton® 100H Type” (Kapton is a registered trademark in Japan, other countries, or both), thickness: 25 μm) cut to a diameter of 120 mm as an insulating support layer was placed at the bottom of a stainless steel mold (diameter: 120 mm, height: 100 mm). 30 ml of the CNT dispersion liquid was charged into the mold in which the polyimide film was placed, from above the polyimide film. After the charging, the CNT dispersion liquid was natural dried for 48 hr or more. Subsequently, the mold was vacuum dried in a vacuum drier at a temperature of 100° C. for 24 hr to remove the solvent, thus simultaneously producing an electromagnetic wave shield layer formed on the polyimide film and an electromagnetic wave shield structure in which an electromagnetic wave shield layer was formed on the polyimide film. The area of the electromagnetic wave shield layer after drying used in the calculation of the mass per unit area can be determined from the diameter of the polyimide film.

### Comparative Example 1

Fibrous carbon nanostructures, a CNT dispersion liquid, an electromagnetic wave shield layer, and an electromagnetic wave shield structure were produced in the same way as in Example 1, except that no surface-treated fibrous carbon nanostructures were prepared, i.e. the obtained SWCNTs were directly used, a preliminary dispersion liquid containing the SWCNTs and resin was obtained in the following manner in the preparation of the dispersion liquid, and a drying method (described in detail below) was used instead of the filtering in the formation of the electromagnetic wave shield layer.

Measurement was performed in the same way as in Example 1. The results are shown in Table 1.

### [Preparation of Dispersion Liquid]

The untreated SWCNTs obtained as described above and fluororesin as another component were added to methyl ethyl ketone as an organic solvent so as to have a total concentration of 0.2% in a proportion of 5 parts of the SWCNTs to 100 parts of the fluororesin, and stirred with a magnetic stirrer for 24 hr to obtain a preliminary dispersion liquid containing the SWCNTs and the fluororesin.

Next, the preliminary dispersion liquid was charged into a multistage step-down high-pressure homogenizer (manufactured by Beryu Corporation, product name “BERYU SYSTEM PRO”) having a multistage pressure controller (multistage step-down transformer) connected to a high-pressure dispersion treatment portion (jet mill) having a thin-tube flow path portion with a diameter of 200 μm. A pressure of 120 MPa was applied to the charged preliminary dispersion liquid intermittently and instantaneously, to perform a dispersion process once while transferring the preliminary dispersion liquid into the thin-tube flow path. A CNT dispersion liquid containing the fibrous carbon nanostructures, the fluororesin, and the solvent was thus obtained.

### [Formation of Electromagnetic Wave Shield Layer]

A polyimide film (manufactured by DuPont-Toray Co., Ltd., product name “Kapton® 100H Type” (Kapton is a registered trademark in Japan, other countries, or both), thickness: 25 μm) cut to a diameter of 120 mm as an insulating support layer was placed at the bottom of a stainless steel mold (diameter: 120 mm, height: 100 mm). 550 ml of the CNT dispersion liquid was charged into the mold in which the polyimide film was placed, from above the polyimide film. After the charging, the CNT dispersion liquid was natural dried for 48 hr or more. Subsequently, the mold was vacuum dried in a vacuum drier at a temperature of 100° C. for 24 hr to remove the solvent, thus simultaneously producing an electromagnetic wave shield layer formed on the polyimide film and an electromagnetic wave shield structure in which an electromagnetic wave shield layer was formed on the polyimide film. The area of the electromagnetic wave shield layer after drying used in the calculation of the mass per unit area can be determined from the diameter of the polyimide film.

### Comparative Example 2

Fibrous carbon nanostructures, a CNT dispersion liquid, an electromagnetic wave shield layer, and an electromagnetic wave shield structure were produced in the same way as in Example 1, except that no surface-treated fibrous carbon nanostructures were prepared, i.e. the obtained SWCNTs were directly used, and the amount of the CNT dispersion liquid used for the filtering was changed to 40 ml in the formation of the electromagnetic wave shield layer.

Measurement was performed in the same way as in Example 1. The results are shown in Table 1.

### Comparative Example 3

Fibrous carbon nanostructures, a CNT dispersion liquid, an electromagnetic wave shield layer, and an electromagnetic wave shield structure were produced in the same way as in Example 1, except that no surface-treated fibrous carbon nanostructures were prepared, i.e. the obtained SWCNTs were directly used, and the amount of the CNT dispersion liquid used for the filtering was changed to 400 ml in the formation of the electromagnetic wave shield layer.

Measurement was performed in the same way as in Example 1. The results are shown in Table 1.

### Comparative Example 4

Fibrous carbon nanostructures, a CNT dispersion liquid, an electromagnetic wave shield layer, and an electromagnetic wave shield structure were produced in the same way as in Example 1, except that no surface-treated fibrous carbon nanostructures were prepared, i.e. the obtained SWCNTs were directly used, and a drying method (described in detail below) was used instead of the filtering in the formation of the electromagnetic wave shield layer.

Measurement was performed in the same way as in Example 1. The results are shown in Table 1.

### [Formation of Electromagnetic Wave Shield Layer]

A polyimide film (manufactured by DuPont-Toray Co., Ltd., product name “Kapton® 100H Type” (Kapton is a registered trademark in Japan, other countries, or both), thickness: 25 μm) cut to a diameter of 120 mm as an insulating support layer was placed at the bottom of a stainless steel mold (diameter: 120 mm, height: 100 mm). 30 ml of the CNT dispersion liquid was charged into the mold in which the polyimide film was placed, from above the polyimide film. After the charging, the CNT dispersion liquid was natural dried for 48 hr or more. Subsequently, the mold was vacuum dried in a vacuum drier at a temperature of 100° C. for 24 hr to remove the solvent, thus simultaneously producing an electromagnetic wave shield layer formed on the polyimide film and an electromagnetic wave shield structure in which an electromagnetic wave shield layer was formed on the polyimide film. The area of the electromagnetic wave shield layer after drying used in the calculation of the mass per unit area can be determined from the diameter of the polyimide film.

### Comparative Example 5

A CNT dispersion liquid, an electromagnetic wave shield layer, and an electromagnetic wave shield structure were produced in the same way as in Example 1, except that MWCNTs (manufactured by Nanocyl SA, product name “NC7000”, BET specific surface area: 265 m²/g, average fiber diameter: 10 nm, average fiber length: 1.5 μm) were used instead of the SWCNTs prepared as described above in the preparation of the fibrous carbon nanostructures, no surface-treated fibrous carbon nanostructures were prepared, i.e. the obtained MWCNTs were directly used, and a drying method (described in detail below) was used instead of the filtering in the formation of the electromagnetic wave shield layer.

Measurement was performed in the same way as in Example 1. The results are shown in Table 1.

### [Formation of Electromagnetic Wave Shield Layer]

A polyimide film (manufactured by DuPont-Toray Co., Ltd., product name “Kapton® 100H Type” (Kapton is a registered trademark in Japan, other countries, or both), thickness: 25 μm) cut to a diameter of 120 mm as an insulating support layer was placed at the bottom of a stainless steel mold (diameter: 120 mm, height: 100 mm). 50 ml of the CNT dispersion liquid was charged into the mold in which the polyimide film was placed, from above the polyimide film. After the charging, the CNT dispersion liquid was natural dried for 48 hr or more. Subsequently, the mold was vacuum dried in a vacuum drier at a temperature of 100° C. for 24 hr to remove the solvent, thus simultaneously producing an electromagnetic wave shield layer formed on the polyimide film and an electromagnetic wave shield structure in which an electromagnetic wave shield layer was formed on the polyimide film. The area of the electromagnetic wave shield layer after drying used in the calculation of the mass per unit area can be determined from the diameter of the polyimide film.

TABLE 1

| | | | Ex. 1 | Ex. 2 | | Ex. 3 | Ex. 4 | Ex. 5 | Ex. 6 | Ex. 7 |
|---|---|---|---|---|---|---|---|---|---|---|
| Fibrous | Type | | SWCNT | SWCNT | | SWCNT | SWCNT | SWCNT | MWCNT | SWCNT |
| carbon | BET specific | | 880 | 880 | | 880 | 880 | 880 | 265 | 880 |
| nano- | surface area [m²/g] | | | | | | | | | |
| structures | | | | | | | | | | |
| Surface- | Surface | Method | Atmo- | Atmo- | | Ni- | Ni- | Ozone | Ozone | Atmo- |
| treated | treatment | | spheric | spheric | | trogen | trogen | | | spheric |
| fibrous | | | discharge | discharge | | discharge | discharge | | | discharge |
| carbon | | | plasma | plasma | | plasma | plasma | | | plasma |
| nano- | | Treat- | 0.5 | 2 | | 0.5 | 2 | 24 | 48 | 0.5 |
| structures | | ment | | | | | | | | |
| | | time | | | | | | | | |
| | | [hr] | | | | | | | | |
| | Oxygen element | | 0.187 | 0.295 | | 0.083 | 0.221 | 0.171 | 0.099 | 0.187 |
| | content | | | | | | | | | |
| | [times vs. carbon | | | | | | | | | |
| | element content] | | | | | | | | | |
| | Nitrogen element | | 0.010 | 0.019 | | 0.027 | 0.103 | 0 | 0 | 0.010 |
| | content | | | | | | | | | |
| | [times vs. carbon | | | | | | | | | |
| | element content] | | | | | | | | | |
| Other component | | Type | — | — | | — | — | — | — | — |
| Electro- | Electro- | Mass per | 6.3 | 2.8 | | 16.4 | 27.8 | 15.7 | 3.3 | 1.8 |
| magnetic | magnetic | unit area | | | | | | | | |
| wave | wave | [g/m²] | | | | | | | | |
| shield | shield layer | Thick- | 22 | 10 | | 67 | 96 | 55 | 10 | 7 |
| structure | | ness | | | | | | | | |
| | | [μm] | | | | | | | | |
| | Insulating | Type | — | — | | — | — | — | Poly- | Poly- |
| | support | | | | | | | | imide | imide |
| | layer | Thick- | — | — | | — | — | — | 25 | 25 |
| | | ness | | | | | | | | |
| | | [μm] | | | | | | | | |
| Eval- | Electro- | 60 GHz | 5.1 | 5.8 | | 4.2 | 5.9 | 4.5 | 4.4 | 4.6 |
| uation | magnetic | [dB] | | | | | | | | |
| | wave | 75 GHz | 5.9 | 6.2 | | 4.5 | 6.3 | 5.8 | 4.5 | 5.8 |
| | absorption | [dB] | | | | | | | | |
| | performance | 90 GHz | 7.1 | 7.6 | | 5.9 | 7.8 | 7.0 | 5.3 | 6.9 |
| | (reflection | [dB] | | | | | | | | |
| | attenuation | | | | | | | | | |
| | amount) | | | | | | | | | |
| | Electro- | 60 GHz | 57 | 52 | | 60 | 51 | 58 | 61 | 57 |
| | magnetic | [dB] | | | | | | | | |
| | wave | 75 GHz | 56 | 53 | | 62 | 51 | 56 | 58 | 56 |
| | shield | [dB] | | | | | | | | |
| | performance | 90 GHz | 64 | 60 | | 68 | 58 | 63 | 60 | 62 |
| | (transmission | [dB] | | | | | | | | |
| | attenuation | | | | | | | | | |
| | amount) | | | | | | | | | |
| | | | | | | Comp. | Comp. | Comp. | Comp. | Comp. |
| | | | | | | Ex. 1 | Ex. 2 | Ex. 3 | Ex. 4 | Ex. 5 |
| | | | Fibrous | Type | | SWCNT | SWCNT | SWCNT | SWCNT | MWCNT |
| | | | carbon | BET specific | | 880 | 880 | 880 | 880 | 265 |
| | | | nano- | surface area | | | | | | |
| | | | structures | [m²/g] | | | | | | |
| | | | Surface- | Surface | Method | No | No | No | No | No |
| | | | treated | treatment | | treat- | treat- | treat- | treat- | treat- |
| | | | fibrous | | | ment | ment | ment | ment | ment |
| | | | carbon | | Treat- | — | — | — | — | — |
| | | | nano- | | ment | | | | | |
| | | | structures | | time | | | | | |
| | | | | | [hr] | | | | | |
| | | | | Oxygen element | | 0.013 | 0.013 | 0.013 | 0.013 | 0.003 |
| | | | | content | | | | | | |
| | | | | [times vs. carbon | | | | | | |
| | | | | element content] | | | | | | |
| | | | | Nitrogen element | | 0 | 0 | 0 | 0 | 0 |
| | | | | content | | | | | | |
| | | | | [times vs. carbon | | | | | | |
| | | | | element content] | | | | | | |
| | | | Other component | | Type | Fluoro- | — | — | — | — |
| | | | | | | resin | | | | |
| | | | Electro- | Electro- | Mass per | 32.6 | 2.9 | 27.5 | 1.4 | 3.2 |
| | | | magnetic | magnetic | unit area | | | | | |
| | | | wave | wave | [g/m²] | | | | | |
| | | | shield | shield layer | Thick- | 120 | 10 | 95 | 5 | 9 |
| | | | structure | | ness | | | | | |
| | | | | | [μm] | | | | | |
| | | | | Insulating | Type | Poly- | — | — | Poly- | Poly- |
| | | | | support | | imide | | | imide | imide |
| | | | | layer | Thick- | 25 | — | — | 25 | 25 |
| | | | | | ness | | | | | |
| | | | | | [μm] | | | | | |
| | | | Eval- | Electro- | 60 GHz | 1.2 | 2.7 | 2.9 | 2.6 | 2.0 |
| | | | uation | magnetic | [dB] | | | | | |
| | | | | wave | 75 GHz | 1.1 | 1.7 | 1.8 | 1.7 | 1.5 |
| | | | | absorption | [dB] | | | | | |
| | | | | performance | 90 GHz | 1.1 | 1.8 | 2.0 | 1.8 | 1.6 |
| | | | | (reflection | [dB] | | | | | |
| | | | | attenuation | | | | | | |
| | | | | amount) | | | | | | |
| | | | | Electro- | 60 GHz | 52 | 65 | 68 | 66 | 63 |
| | | | | magnetic | [dB] | | | | | |
| | | | | wave | 75 GHz | 51 | 68 | 69 | 67 | 64 |
| | | | | shield | [dB] | | | | | |
| | | | | performance | 90 GHz | 52 | 71 | 74 | 70 | 66 |
| | | | | (transmission | [dB] | | | | | |
| | | | | attenuation | | | | | | |
| | | | | amount) | | | | | | |

As can be understood from Table 1, in the case of including the electromagnetic wave shield layer of Comparative Example 1 that used untreated fibrous carbon nanostructures without surface treatment and whose mass per unit area was outside a predetermined range, the electromagnetic wave absorption performance was particularly poor, and excellent electromagnetic wave shield performance and electromagnetic wave absorption performance were unable to be achieved.

In the case of including the electromagnetic wave shield layer of each of Comparative Examples 2 to 5 that used untreated fibrous carbon nanostructures without surface treatment and whose mass per unit area was within the predetermined range, favorable electromagnetic wave shield performance was maintained as compared with Comparative Example 1, but the electromagnetic wave absorption performance was not improved sufficiently.

In the case of including the electromagnetic wave shield layer of each of Examples 1 to 7 that used surface-treated fibrous carbon nanostructures obtained by surface treatment and whose mass per unit area was 0.5 g/m² or more and 30 g/m² or less, the electromagnetic wave shield structure had excellent electromagnetic wave shield performance and electromagnetic wave absorption performance in an extremely high frequency band.

### INDUSTRIAL APPLICABILITY

It is thus possible to provide an electromagnetic wave shield structure excellent in electromagnetic wave shield performance and electromagnetic wave absorption performance in an extremely high frequency band (in particular millimeter waves of 30 GHz or more), and a production method therefor.

1. An electromagnetic wave shield structure comprising
an electromagnetic wave shield layer that contains surface-treated fibrous carbon nanostructures obtained by treating surfaces of fibrous carbon nanostructures and has a weight per unit area of 0.5 g/m² or more and 30 g/m² or less.

2. The electromagnetic wave shield structure according to claim 1, wherein at surfaces of the surface-treated fibrous carbon nanostructures, an amount of an oxygen element is 0.03 times or more and 0.3 times or less an amount of a carbon element and/or an amount of a nitrogen element is 0.005 times or more and 0.2 times or less the amount of the carbon element.

3. The electromagnetic wave shield structure according to claim 2, wherein at the surfaces of the surface-treated fibrous carbon nanostructures, the amount of the oxygen element is 0.03 times or more and 0.3 times or less the amount of the carbon element and the amount of the nitrogen element is 0.005 times or more and 0.2 times or less the amount of the carbon element.

4. The electromagnetic wave shield structure according to claim 1, wherein the fibrous carbon nanostructures include carbon nanotubes.

5. The electromagnetic wave shield structure according to claim 1, wherein the surface-treated fibrous carbon nanostructures are 75 mass % or more of the electromagnetic wave shield layer.

6. The electromagnetic wave shield structure according to claim 1, further comprising
an insulating support layer directly or indirectly adhered to the electromagnetic wave shield layer.

7. A production method for the electromagnetic wave shield structure according to claim 1, the production method comprising
a step (A) of forming an electromagnetic wave shield layer that has a weight per unit area of 0.5 g/m² or more and 30 g/m² or less, using surface-treated fibrous carbon nanostructures obtained by treating surfaces of fibrous carbon nanostructures,
wherein the step (A) includes: a step (A-2) of dispersing the surface-treated fibrous carbon nanostructures in a solvent to obtain a dispersion liquid; and a step (A-3) of removing the solvent from the dispersion liquid to form the electromagnetic wave shield layer.

8. The production method according to claim 7, wherein in the step (A-3), the dispersion liquid is filtered to remove the solvent.

9. The production method according to claim 7, wherein in the step (A-3), the dispersion liquid is dried to remove the solvent.

10. The production method according to claim 7, wherein the step (A) further includes a step (A-1) of subjecting the surfaces of the fibrous carbon nanostructures to plasma treatment and/or ozone treatment to obtain the surface-treated fibrous carbon nanostructures.
